(19) United States
(12) Patent Application Publication
(10) Pub. No.: US 2004/0012937 A1
(43) Pub. Date: Jan. 22, 2004

(54) Method for manufacturing a printed circuit board substrate with passive electrical components

(75) Inventors: David DeGrappo, Doylestown, PA (US); Richard Dow, Philadelphia, PA (US); Timothy W. Ellis, Doylestown, PA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: KULICKE & SOFFA INVESTMENTS, INC., Wilmington, DE (US)

(21) Appl. No.: 10/199,484

(22) Filed: Jul. 18, 2002

(51) Int. Cl. H05K 7/02

(52) U.S. Cl. 361/782

(57) ABSTRACT

A process for manufacturing a Printed Circuit Board (PCB) substrate with passive electrical components (e.g., capacitors, inductors and/or resistors) includes weaving a plurality of dielectric strands (e.g., fiberglass yarns) and at least one electrically conductive strand (e.g., a copper wire) to form a woven fabric. The woven fabric is impregnated with a dielectric resin material to form an impregnated fabric and, thereafter, the impregnated fabric is cured to form a cured fabric. The cured fabric's upper and lower surfaces are then planed. The planing of the upper and lower surface segments the electrically conductive strands and forms a PCB substrate with a passive electrical component (e.g., a capacitor and/or inductor) therein. The passive electrical component(s) includes electrically isolated conductive strand segments separated by at least one of the dielectric resin material and the dielectric strands. A PCB substrate with passive electrical components formed therein includes a planarized woven fabric with a cured dielectric resin material impregnated therein. The planarized woven fabric includes a planed upper surface, a planed lower surface and a plurality of integrally formed electrically conductive strand segments (e.g., copper wire segments) configured as electrically conductive portions of a passive electrical component. The cured dielectric resin material is disposed between the integrally formed conductive strand segments.

### BACKGROUND OF THE INVENTION

1. Field of the Invention

The present invention relates, in general, to semiconductor device packaging and, in particular, to printed circuit board (PCB) substrates with passive electrical components and methods for their manufacture.

2. Description of the Related Art

Conventional Printed Circuit Board (PCB) substrates serve as a base for the mechanical support and electrical interconnection of passive electrical components (e.g., capacitors, inductors and resistors) and/or active electrical components (e.g., integrated circuits). FIG. 1 is a simplified cross-sectional diagram of a portion of a conventional PCB substrate 10 with a passive electrical component 12 mounted thereon.

Conventional PCB substrate 10 includes a sheet-like base 14 formed of an electrically non-conductive material (e.g., a glass material). Sheet-like base 14 has an upper surface 16 and a lower surface 18. Conventional PCB substrate 10 also includes a plurality of electrically conductive vias 20 (only one of which is shown in FIG. 1) that extend from upper surface 16 to lower surface 18.

Conventional PCB substrates are typically manufactured by initially forming a sheet-like base of non-conductive material. The sheet-like base can be formed, for example, by weaving glass fibers to form a sheet of cloth. The sheet of cloth is then dipped in resin and thermally cured to form the sheet-like base. Thereafter, via holes are mechanically drilled through the sheet-like base, plated and filled with an electrically conductive material (e.g., copper) to form electrically conductive vias.

Once a conventional PCB substrate is manufactured, individual passive electrical components are frequently mounted on the PCB substrate surface and electrically coupled to vias of the PCB substrate. The mounting process is a time-consuming, low throughput and expensive process. In addition, the mounting of passive electrical components on a PCB substrate consumes surface area that could otherwise be used for the mounting of active electrical components (e.g., integrated circuits), resulting in a relatively large PCB substrate.

Still needed in the field, therefore, is an inexpensive and high throughput method for manufacturing a PCB substrate with passive electrical components, (e.g., capacitors, inductors, resistors). Also needed is an inexpensive and compact PCB substrate with passive electrical components.

### SUMMARY OF THE INVENTION

The present invention provides an inexpensive and high throughput process for manufacturing a Printed Circuit Board (PCB) substrate with passive electrical components (e.g., capacitors and/or inductors and/or resistors).

A process according to one exemplary embodiment of the present invention includes first weaving a plurality of dielectric strands (e.g., fiberglass yarns) and at least one electrically conductive strand (e.g., a copper wire) to form a woven fabric. The woven fabric thus formed has an upper surface and a lower surface.

Next, the woven fabric is impregnated with a dielectric resin material to form an impregnated fabric and, thereafter, the impregnated fabric is cured to form a cured fabric. The geometry (e.g., spacing and overlap) of the electrically conductive strand(s) is controlled during the weaving step to form the basic structure of a passive electrical component(s) within the woven fabric prior to impregnation with the dielectric resin material. Furthermore, properties (e.g., capacitance or inductance) of the passive electrical component(s) are obtained and controlled by the predetermined selection of the geometry produced by the weaving process. In addition to the geometry produced by the weaving process, the electrical properties of the dielectric strands, electrically conductive strand(s) and dielectric resin material provide for the formation of a variety of passive electrical components including, but not limited to, resistors, capacitors and inductors.

The cured fabric's upper and lower surfaces are then planed. The planing of the upper and lower surface segments the electrically conductive strands and forms a PCB substrate with a passive electrical component (e.g., a capacitor and/or resistor and/or inductor) therein. The PCB substrate formed by the planing step includes a planarized cured fabric with an upper planed surface, a lower planed surface and the aforementioned passive electrical component. The passive electrical component includes electrically isolated conductive strand segments separated by at least one of the dielectric resin material and the dielectric strands.

Weaving is a reliable, inexpensive and high throughput process technology in comparison to the mechanical mounting techniques conventionally used to mount passive electrical components on a PCB substrate manufacturing. Therefore, processes according to one exemplary embodiment of the present invention provide for the inexpensive and high throughput manufacturing of PCB substrates with passive electrical components. It is also noted that the elimination of a separate passive electrical component mounting process reduces the number of assembly steps in comparison to conventional processes.

Also provided by the present invention is an inexpensive and compact PCB substrate with passive electrical components formed therein. The PCB substrate includes a planarized woven fabric with a cured dielectric resin material impregnated therein. The planarized woven fabric includes a planed upper surface, a planed lower surface and a plurality of integrally formed electrically conductive strand segments (e.g., copper wire segments) configured as electrically conductive portions of a passive electrical component(s) (e.g., a resistor, and/or capacitor and/or inductor). The cured dielectric resin material is disposed between the integrally formed conductive strand segments configured as electrically conductive portions of a passive electrical component. Since the passive electrical components are integrally formed within the PCB board substrate, the PCB board substrate is compact in size. In addition, since the electrically conductive strand portions are formed integrally with the remainder of the PCB substrate, the PCB substrate can be inexpensively manufactured.

A better understanding of the features and advantages of the present invention will be obtained by reference to the following detailed description that sets forth illustrative embodiments, in which the principles of the invention are utilized, and the accompanying drawings.

### BRIEF DESCRIPTION OF THE DRAWINGS

FIG. 1 is a simplified cross-sectional diagram of a portion of a conventional PCB substrate;

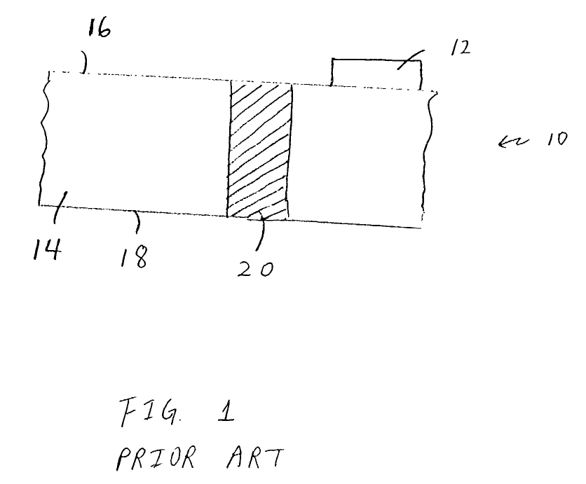

FIG. 2 is a flow chart illustrating a sequence of steps in a process according to one exemplary embodiment of the present invention;

FIG. 3 is a simplified perspective view of a woven fabric formed according to a step of an exemplary embodiment of the present invention;

FIG. 4 is a simplified cross-sectional side view of a PCB substrate formed according to a step of an exemplary embodiment of the present invention; and

FIG. 5 is a cross-sectional side view of PCB substrate with a passive electrical component (i.e., a capacitor) according to an exemplary embodiment of the present invention.

### DETAILED DESCRIPTION OF THE INVENTION

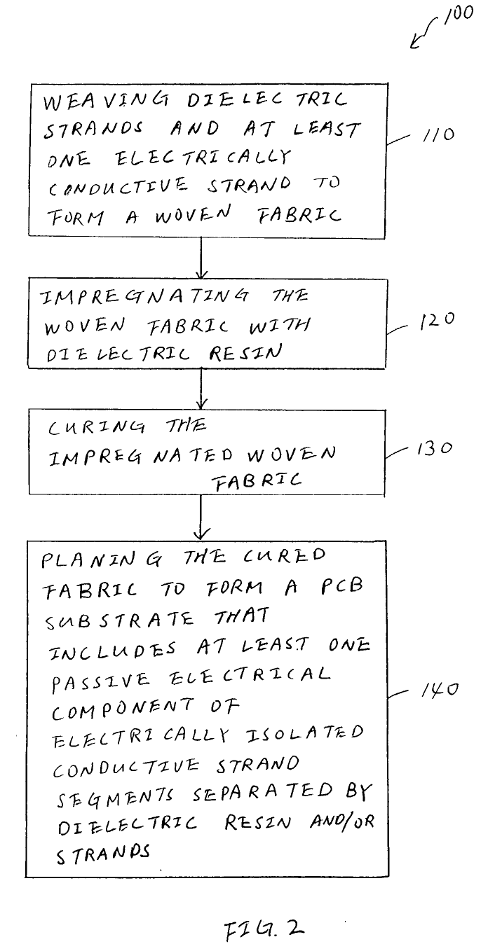

FIG. 2 is a flow chart illustrating a sequence of steps in a process 100 for manufacturing a PCB substrate with passive electrical components (e.g., capacitors, inductors and/or resistors) in accordance with an exemplary embodiment of the present invention. Process 100 includes weaving a plurality of dielectric strands and at least one electrically conductive strand (e.g., a copper wire) to form a woven fabric with an upper surface and a lower surface, as set forth in step 110. Weaving step 110 can form the woven fabric using any suitable weaving technique including, for example, a double-layer or triple-layer based plain weaving technique or a Jacquard-based weaving technique. The use of a Jacquard-based weaving technique enables the formation of woven fabrics wherein the dielectric strands and electrically conductive strand(s) are selectively arranged in either of an irregular woven pattern or a regular woven pattern.

Weaving step 110 can be conducted using conventional weaving equipment known to one skilled in the art. Further details related to the weaving of dielectric strands and electrically conductive strands to form a woven fabric during PCB substrate manufacturing are available in commonly-assigned U.S. patent application Ser. No. 10/010,675, filed Nov. 30, 2001, entitled “Method for Manufacturing a Printed Circuit Board Substrate,” which is hereby fully incorporated by reference for all purposes.

The dielectric strands employed in processes according to one exemplary embodiment of the present invention can be any suitable electrically non-conductive strands including, but not limited to, fibers, filaments or yarns formed of glass (such as fiberglass, S-glass or E-glass), polyester or other polymers, Teflon and Kevlar. Exemplary commercial electrically non-conductive strands include Type 1064 Multi-End Roving and Hybon 2022 Roving available from PPG Industries.

If a glass strand is employed, the glass strand can, if desired, be treated with silane to improve its adhesive properties. One skilled in the art will recognize that the electrical characteristics of the dielectric strand can be a factor in determining the electrical characteristics of the passive electrical component.

The conductive strand(s) employed in step 110 can be any suitable conductive strand including, but not limited to, a copper wire, gold wire, aluminum wire, an electrically conductive plastic wire and a combination thereof. The electrically conductive strands can also be, flat ribbon-shaped strands, irregularly-shaped wires, yarns of any suitable cross-section and/or other electrically conductive strands that are not shaped wire.

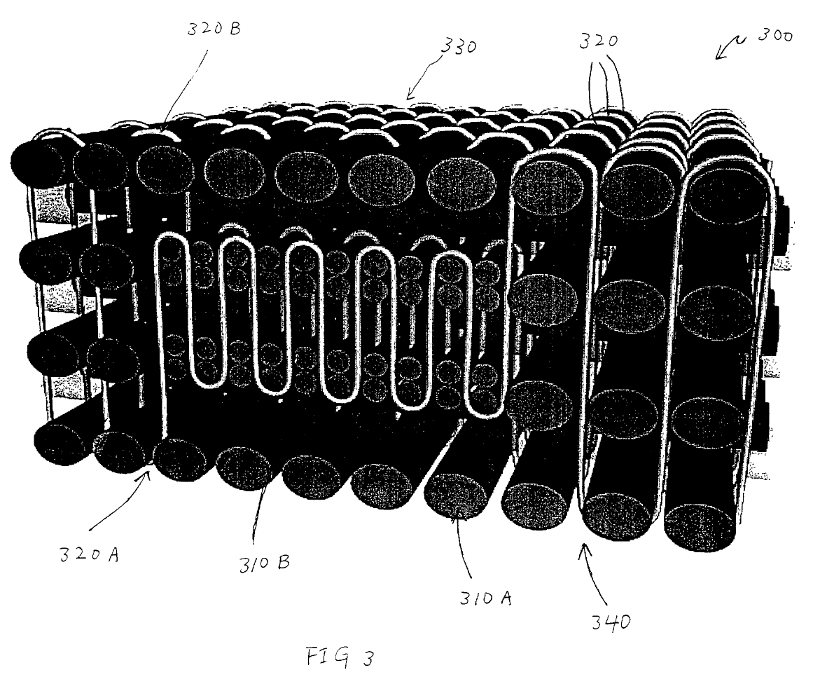

FIG. 3 is a simplified perspective view representations of a portion of one exemplary embodiment of a woven fabric 300 formed by weaving dielectric strands 310 (including dielectric strands 310A and 310B) and electrically conductive strands 320 (including electrically conductive strands 320A and 320B), as set forth in step 110 of FIG. 2. Dielectric strands 310 are of two different diameters, such that dielectric strands 310A are of a greater diameter than dielectric strands 310B.

In the embodiment of FIG. 3, the geometry of electrically conductive strands 320A and 320B woven around dielectric strands 310B forms the basic structure of a passive capacitor. In other words, the basic passive capacitor structure is formed where electrically conductive strands 320A and 320B are woven around dielectric strands 310B. The basic structure of passive capacitor includes two spaced apart electrically conductive strands (i.e., strands 320A and 320B) that are looped 90 degrees out of phase with each other as they pass over dielectric strands 310B. Woven fabric 300 also includes an upper surface 330 and a lower surface 340.

The thickness of the woven fabric formed in step 110 is predetermined based on the required PCB substrate thickness. A typical thickness of the woven fabric is, however, in the range of 2 mm to 22 mm.

Next, the woven fabric is impregnated with a dielectric resin material to form an impregnated fabric, as set forth in step 120 of FIG. 2. The resin material can be any suitable dielectric resin material known to one skilled in the art including, but not limited to, epoxy-based resins, bis-mali-imide based resins, Teflon resins and polyamide resins. Impregnation of the woven fabric with the dielectric resin material can be accomplished using conventional techniques. The dielectric properties of polymeric resins and polymeric dielectric strands (or fibers), e.g. E-Glass with a δ=6.75 @ 100 mc and Epoxy with a δ=3.6 @ 1 Mhz, are particularly useful for separating the electrically conductive strands of a passive electrical component.

Next, the impregnated fabric is cured to form a cured fabric, as set forth in step 130. The curing can be accomplished, for example, using conventional thermal and/or ultraviolet curing techniques. Although curing process parameters are dependent on the dielectric resin material used to impregnate the woven fabric, curing step 130 is typically conducted in a nitrogen or air ambient, at a temperature in the range of 125° C. to 200° C., and for a time period in the range of 15 minutes to 2 hours.

After curing of the impregnated fabric, the upper and lower surfaces of the cured fabric are subsequently planed, as set forth in step 140. This planing step serves to segment the at least one conductive strand and form a PCB substrate that includes a planarized cured fabric with an upper planed surface, a lower planed surface and at least one passive electrical component. The passive electrical component thus formed includes electrically isolated conductive strand segments separated by at least one of the dielectric resin material and dielectric strands.

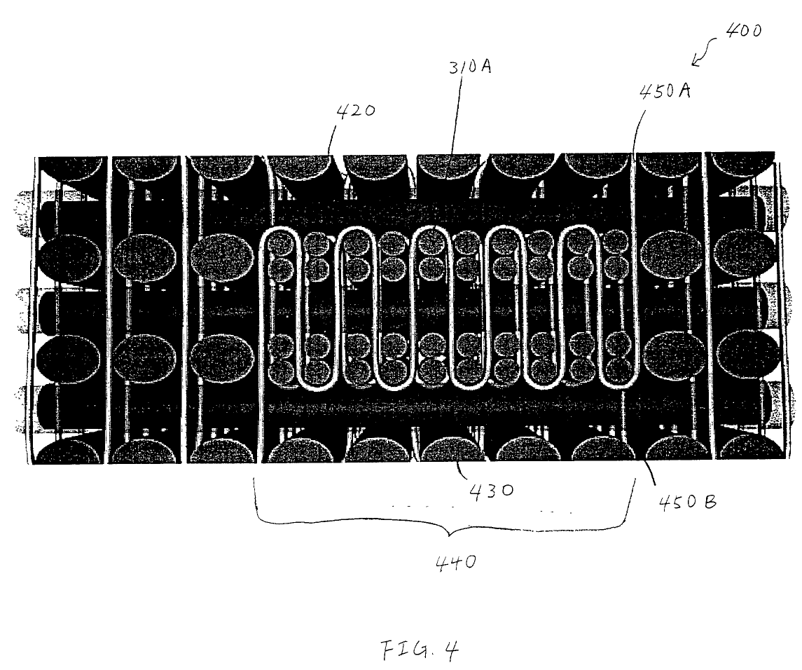

FIG. 4 is a simplified cross-sectional side view of a portion of one exemplary embodiment of a PCB substrate 400 formed by planing a cured fabric as set forth in step 140 of FIG. 2. In the embodiment of FIG. 4, PCB substrate 400 includes a planarized cured fabric 410, an upper planed surface 420, a lower planed surface 430 and a passive capacitor 440. Passive capacitor 440 includes conductive strands 450A and 450B looped 90 degrees out of phase around dielectric strands 310B.

The electrically isolated conductive strand segments and the dielectric material (i.e., the dielectric resin and/or dielectric strand(s)) that separate them can be configured as any suitable passive electrical component including a passive electrical capacitor component, a passive electrical inductor component or a passive electrical resistor component. This can be readily accomplished when the weaving step forms a woven fabric wherein portions of the electrically conductive strand are configured (positioned in a predetermined pattern within the woven fabric, also referred to as the “geometry” of the woven electrically conductive strands) such that they can serve as electrically conductive portions of a passive electrical component. In addition, the electrically conductive portions of the electrically conductive strand can be arranged vertically or horizontally within the woven fabric.

The planing step can be accomplished using grinding techniques, lapping techniques and/or milling techniques (often referred to as “scalping”) known to one skilled in the art. The planing step can remove, for example, 1.0 mm to 0.5 mm from each of the upper and lower surfaces of the cured fabric.

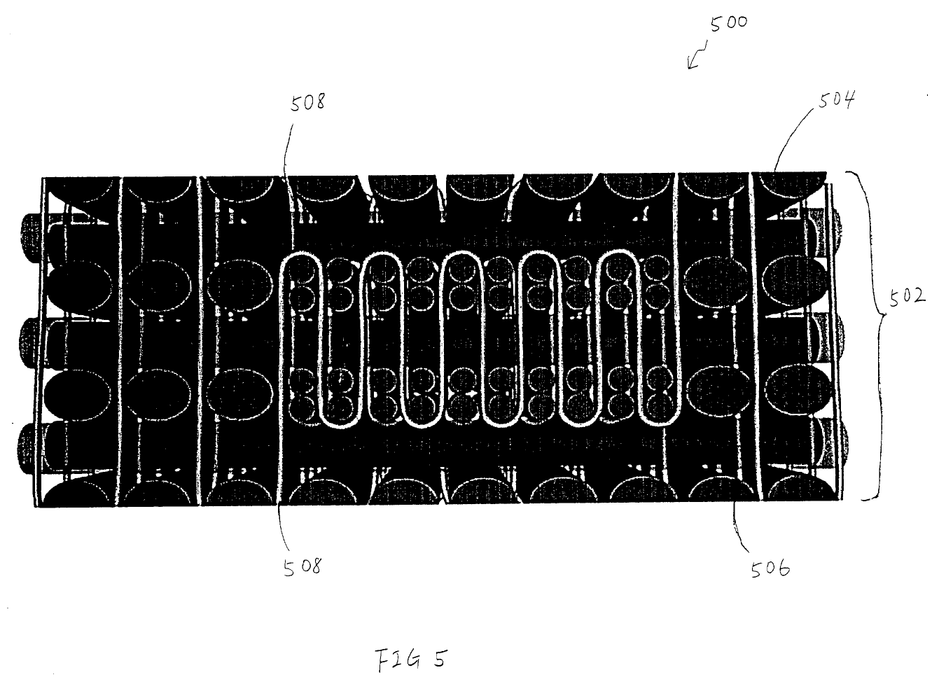

FIG. 5 is a cross-sectional side view of PCB substrate 500 with passive electrical components according to the present invention. PCB substrate 500 includes a planarized woven fabric layer 502 with a planed upper surface 504 and a planed lower surface 506. Planarized woven fabric layer 502 also includes a plurality of integrally formed electrically conductive strand segments 508 (e.g., copper wire segments) configured as electrically conductive portions of a passive capacitor (previously described with respect to FIG. 4). PCB substrate 500 also includes a cured dielectric resin material (not shown in FIG. 5) impregnated in the planarized woven fabric layer and disposed between the integrally formed conductive strand segments configured as electrically conductive portions of a passive electrical component.

Although the embodiment of FIG. 5 includes a passive capacitor, once apprised of the present disclosure, one skilled in the art will recognize that PCB substrates according to the present invention can also include a passive inductor or passive resistor. Such a passive resistor can be formed, for example, by weaving a single electrically conductive strand into a woven fabric, impregnating the woven fabric, curing the impregnated woven fabric and then planning the cured fabric. Similarly, a passive inductor can be formed by weaving two electrically conductive strands into an in-phase looped geometry within a resultant woven fabric.

In one exemplary embodiment, the electrically conductive strands are spaced between 12.5 to 250 microns (0.5-10 mils) apart in the longitudinal direction (the warp direction). Loop control along the warp direction within a conductive strand is controlled by the fill yarns to produce a desired loop spacing. In one exemplary embodiment spacing between adjacent loops in the latitudinal direction is between 12.5 to 625 microns (0.5-25 mils) where a closer spacing (short loop) represents adjacent components next to each other and a further spacing (long loop) represents components across the board from each other that may be separated by, for example, one or more output pins. The height of a typical conductive strand through the board depends on the thickness of the board. Typically the height of a conductive strand is at least 25 microns and in some embodiments it is between 25 and 100 microns.

It should be understood that various alternatives to the embodiments of the invention described herein may be employed in practicing the invention. It is intended that the following claims define the scope of the invention and that structures and methods within the scope of these claims and their equivalents be covered thereby.

What is claimed is:

1. A method for manufacturing a printed circuit board (PCB) substrate that includes at least one passive electrical structure, the method comprising:
weaving a plurality of dielectric strands and at least one electrically conductive strand to form a woven fabric;
impregnating the woven fabric with a dielectric resin material to form an impregnated fabric;
curing the impregnated fabric to form a cured fabric; and
planing upper and lower surfaces of the cured fabric, thereby segmenting the at least one conductive strand and forming a PCB substrate that includes a planarized cured fabric with an upper planed surface, a lower planed surface and at least one passive electrical component, the passive electrical component including:
electrically isolated conductive strand segments separated by at least one of the dielectric resin material and dielectric strands.

2. The method of claim 1 wherein the planing step forms a PCB substrate that includes at least one passive electrical capacitor component.

3. The method of claim 1 wherein the planing step forms a PCB substrate that includes at least one passive electrical inductor component.

4. The method of claim 1 wherein the planing step forms a PCB substrate that includes at least one passive electrical resistor component.

5. The method of claim 1 wherein the plurality of dielectric strands are dielectric yarns.

6. The method of claim 5 wherein the plurality of dielectric yarns are fiberglass yarns.

7. The method of claim 1 wherein the electrically conductive strand is a copper wire.

8. The method of claim 1 wherein the weaving step employs a plain weaving based technique.

9. The method of claim 1 wherein the weaving step employs a double-layer plain weaving based technique.

10. The method of claim 1 wherein the weaving step forms a triple-layer plain weaving based woven fabric.

11. The method of claim 1 wherein the weaving step employs a Jacquard-based weaving technique.

12. The method of claim 1 wherein the weaving step forms a woven fabric wherein portions of the electrically conductive strand are configured as electrically conductive portions of a passive electrical component.

13. A printed circuit board (PCB) substrate with passive electrical components comprising:
a planarized woven fabric layer with a planed upper surface and a planed lower surface, the planarized woven fabric layer including a plurality of integrally formed electrically conductive strand segments configured as electrically conductive portions of a passive electrical component; and
a cured dielectric resin material impregnated in the planarized woven fabric layer and disposed between the integrally formed conductive strand segments configured as electrically conductive portions of a passive electrical component.

14. The PCB substrate with passive electrical components of claim 13 wherein the electrically conductive strand segments are configured as a passive electrical capacitor component.

15. The PCB substrate with passive electrical components of claim 13 wherein the electrically conductive strand segments are configured as a passive electrical inductor component.

16. The PCB substrate with passive electrical components of claim 14 wherein the electrically conductive strand segments are configured as a passive electrical resistor component.
